(19) United States
(12) Patent Application Publication
(10) Pub. No.: US 2007/0096839 A1
(43) Pub. Date: May 3, 2007

(54) Temperature compensation circuit for a surface acoustic wave oscillator

(76) Inventor: Vern Meissner, Niles, IL (US)

Correspondence Address: DANIEL J. DENEUFBOURG;CTS CORPORATION, 171 COVINGTON DRIVE, BLOOMINGDALE, IL, 60108, US

(21) Appl. No.: 11/265,634

(22) Filed: Nov. 2, 2005

(51) Int. Cl. H03L 1/00

(52) U.S. Cl. 331/176

(57) ABSTRACT

A surface acoustic wave oscillator includes a temperature sensor adapted to generate a temperature sensor signal. A temperature signal conditioner is coupled to the temperature sensor. The temperature signal conditioner receives the temperature sensor signal and generates a conditioned temperature sensor signal. A reactance generator is coupled to the temperature signal conditioner. The reactance generator receives the conditioned temperature sensor signal and generates a compensation signal. A surface acoustic wave device is coupled to the reactance generator. An oscillator circuit is coupled to the surface acoustic wave device.

### FIELD OF THE INVENTION

This invention relates to surface acoustic wave oscillators and, in particular, to temperature compensated high-frequency surface acoustic wave frequency oscillators.

### DESCRIPTION OF THE RELATED ART

High capacity data networks rely on signal repeaters and sensitive receivers for low-error data transmission. To decode and/or cleanly re-transmit a serial data signal, such network components include components for creating a data timing signal having the same phase and frequency as the data signal. This step of creating a timing signal has been labeled “clock recovery.”

Data clock recovery requires a relatively high purity reference signal to serve as a starting point for matching the serial data signal clock rate and also requires circuitry for frequency adjustment. The type, cost and quality of the technology employed to generate the high purity reference signal vary according to the class of data network application. For fixed large-scale installations, an “atomic” clock may serve as the ultimate source of the reference signal. For remote or movable systems, components including specially configured quartz resonators have been used. As communication network technology progresses towards providing higher bandwidth interconnections to local area networks and computer workstations, the need has grown for smaller, higher frequency, and less-expensive clock recovery technology solutions.

For higher frequency applications now in demand, e.g., above 500 MHz, more conventional resonator technologies such as standard AT-cut quartz crystals have not been fully successful. The recognized upper limit for fundamental-mode, straight blank AT-cut crystals is about 70 MHz and the upper limit for mesa crystal technologies is about 200 MHz. In order to utilize crystals in these higher frequency applications, PLL circuits or analog multipliers are used to increase the base crystal frequency by factors of 2×, 4×, 8×, etc. While crystal-based oscillators provide good frequency versus temperature characteristics, the multiplication of the crystal frequency creates adverse sub-harmonics and degrades phase noise performance.

Another solution, in recent years, for frequencies above 500 MHz has been the implementation of surface acoustic wave (SAW) oscillators. While this technology requires no multiplication and hence does not result in any sub-harmonics or degradation in phase noise, the frequency versus temperature performance thereof is on the order of 2× to 10× worse than its uncompensated crystal counterpart.

Therefore, a method to temperature compensate a SAW-based oscillator would provide the benefits of the absence of sub-harmonics and phase noise degradation with the added benefit of good frequency versus temperature response.

A generalized topology to temperature compensate a SAW oscillator is shown in U.S. Pat. No. 4,011,526 to Kinsman which discloses the use of a temperature sensitive voltage source Vs with a SAW oscillator. Unfortunately, the device of Kinsman is not adapted to be efficiently manufactured in significant quantities because the mass production of temperature compensated SAW oscillators requires a circuit topology and method of temperature compensation which accounts for component tolerance variances between individual SAW resonators as well as other circuit components. There thus remains a need for a SAW oscillator which addresses these shortcomings.

### SUMMARY OF THE INVENTION

It is thus a feature of the invention to provide a temperature compensation circuit for a surface acoustic wave oscillator that includes a temperature sensor that is structured to generate a temperature sensor signal and is coupled to a temperature signal conditioner. The temperature signal conditioner receives the temperature sensor signal and generates a conditioned temperature sensor signal. A reactance generator is coupled to the temperature signal conditioner. The reactance generator receives the conditioned temperature sensor signal and generates a compensation signal. A resonator device such as, for example, a surface acoustic wave device is coupled to the reactance generator. An oscillator circuit is coupled to the surface acoustic wave device. The oscillator produces a stable output frequency over a temperature range.

There are other advantages and features that will be more readily apparent from the following description of the invention, the drawings, and the appended exemplary claims.

### BRIEF DESCRIPTION OF THE DRAWINGS

These and other features of the invention can best be understood by the following description of the accompanying drawings as follows:

FIG. 1 is a schematic diagram of a surface acoustic wave oscillator with a temperature compensation circuit in accordance with the present invention;

FIG. 2 is a graph of frequency change versus temperature of an uncompensated SAW oscillator;

FIG. 3 is a graph of capacitance versus temperature for the varactor configuration of the oscillator shown in FIG. 1;

FIG. 4 is a graph of the voltage versus temperature response of a transistor configured as a forward biased diode;

FIG. 5 is a schematic diagram of an alternate embodiment of a reactance generator for the oscillator of the present invention;

FIG. 6 is a graph of the resultant varactor capacitance versus applied voltage at different Voffset voltages;

FIG. 7a is a graph of the voltage versus temperature response of the temperature sensor of the present invention;

FIG. 7b is a graph of the voltage versus temperature response of the temperature sensor signal conditioning circuit of the oscillator of the present invention;

FIG. 7c is a graph of the capacitance versus temperature response of the reactance generator of the oscillator of the present invention; and

FIG. 7d illustrates the resulting frequency versus temperature response of the oscillator of the present invention.

It is noted that the drawings of the invention are not to scale. The drawings are intended to depict only typical embodiments of the invention, and therefore should not be considered as limiting the scope of the invention. The invention will be described with additional specificity and detail through the accompanying drawings.

### DETAILED DESCRIPTION OF THE EMBODIMENTS

Oscillator Circuit

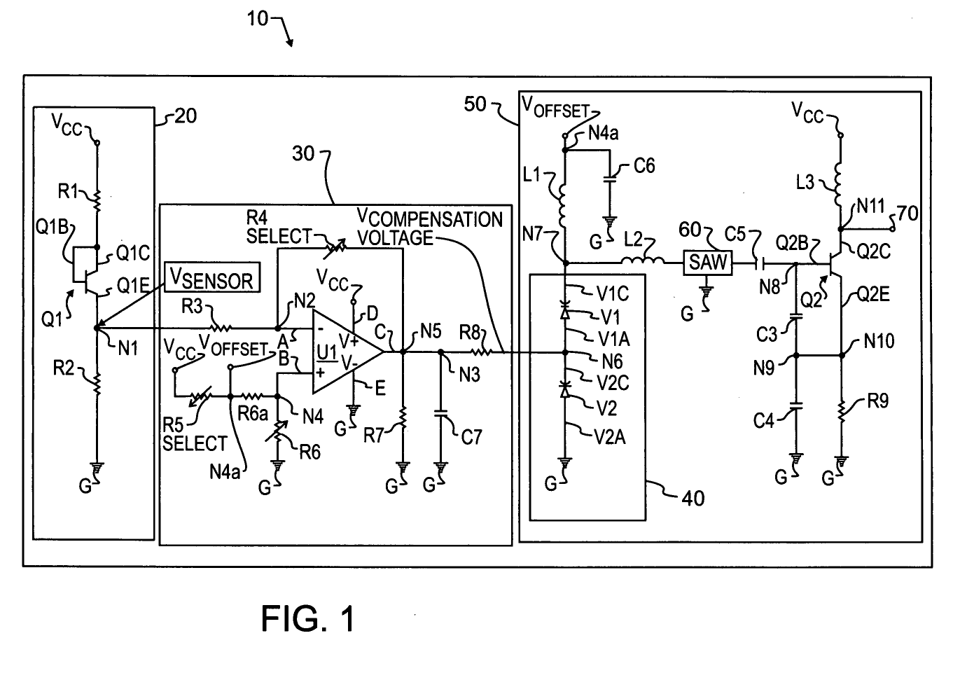

FIG. 1 is a schematic diagram of a surface acoustic wave oscillator 10 with a temperature compensation circuit in accordance with the present invention. Oscillator 10 includes a temperature sensor 20, a temperature signal conditioner 30, a reactance generator 40, an oscillator circuit 50, and a surface acoustic wave resonator (SAW) 60.

Temperature sensor 20 can comprise a transistor Q1 having a base Q1B, an emitter Q1E and a collector Q1C. The base Q1B is connected to collector Q1C. Collector Q1C is connected to a DC power source Vcc through a resistor R1. Power source Vcc is preferably set above Voffset and can be approximately 5 volts. Emitter Q1E is connected to node N1. Node N1 is connected to resistor R2. The other end of resistor R2 is connected to ground G.

Transistor Q1 is adapted to change output voltage in response to a change in temperature. The voltage developed at node N1 therefore is proportional to the temperature that transistor Q1 is subjected to. The voltage at node N1 can be called a temperature sensor signal. Preferably, transistor Q1 is mounted in an electronic package close to SAW resonator 60. In this manner, the temperature of transistor Q1 closely tracks the temperature of SAW resonator 60.

A temperature signal conditioner 30 comprises a differential amplifier U1 having a pair of input terminals A and B, an output terminal C, a power supply terminal D and a ground terminal E. Node N1 is connected to Node N2 through a resistor R3. Input terminal A is connected to node N2. Input terminal B is connected to node N4. Node N4 is connected to resistor R6a and variable resistor R6. Resistor R6 is further connected to ground. Node N4a is connected to a variable resistor R5 and resistor R6a. Resistor R5 is further connected to Vcc. Node N4a is further connected to Voffset.

Power supply terminal D is connected to power supply Vcc and ground terminal E is connected to ground G. Variable resistor R4 has one end connected to node N2 and the other end connected to node N5. Output terminal C is connected to node N5. Resistor R7 is connected between node N5 and ground. Capacitor C7 is connected between node N3 and ground G. Resistor R8 is connected to node N3. Node N3 is connected to node N5. Temperature signal conditioner 30 receives the temperature sensor signal from temperature sensor 20 at node N1 and generates a conditioned temperature sensor signal at node N6. The conditioned temperature sensor signal provides the correct gain and offset voltages to be supplied to reactance generator 40.

Reactance generator 40 comprises a pair of varactors V1 and V2. Varactor V1 has an anode V1A and a cathode V1C. Varactor V2 has an anode V2A and a cathode V2C. Cathode V2C and anode V1A are connected to each other at node N6. Anode V2A is connected to ground G. Cathode V1C is connected to node N7.

Reactance generator 40 receives the conditioned temperature sensor signal at node N6 and generates an oscillator compensation voltage at node N7.

Oscillator 50 is arranged in a Colpitts configuration. Oscillator 50 includes a transistor Q2 having a base Q2B, an emitter Q2E and a collector Q2C. The base Q2B is connected to node N8. Collector Q1C is connected to node N11. Inductor L3 is connected between node N11 and power source Vcc. Node N11 is further connected to oscillator output terminal 70. Emitter Q2E is connected to node N10. Resistor R9 is connected between node N10 and ground G.

A capacitor C3 is connected between node N8 and node N9. Capacitor C4 is connected between node N9 and ground G. Node N9 is connected to node N10. Capacitor C5 has one end connected to node N8 and the other end connected to SAW resonator 60. Inductor L2 has one end connected to node N7 and the other end connected to SAW resonator 60.

SAW resonator 60 can be a surface wave acoustic resonator that is commercially available from TAI-SAW Corporation of Taiwan. SAW resonator 60 resonates at a nominal frequency of 600 MHz. RF choke inductor L1 is connected between node N7 and Voffset. Capacitor C6 is connected between power supply Vcc and ground G.

Oscillator Operation

Individual SAW resonators 60 have variances in their resonant frequency, turning points, and frequency versus temperature response due to manufacturing variations between individual resonators. The components of oscillator 50 and temperature sensor 20 also have variances in their circuit values due to manufacturing variations between individual components.

Signal conditioning circuit 30 matches the response of an individual temperature sensor 20 to an individual saw resonator 60. In order to accurately compensate each individual resonator 60, a compensation technique/circuit must be flexible enough to account for the component tolerances. Signal conditioning circuit 30 is programmable or adjustable in order to match the response of individual SAW resonators 60 (regardless of frequency or manufacturer) to its respective temperature sensor 20. Therefore, each oscillator 10 can be provided a unique temperature compensation solution that results in lower frequency drift with temperature.

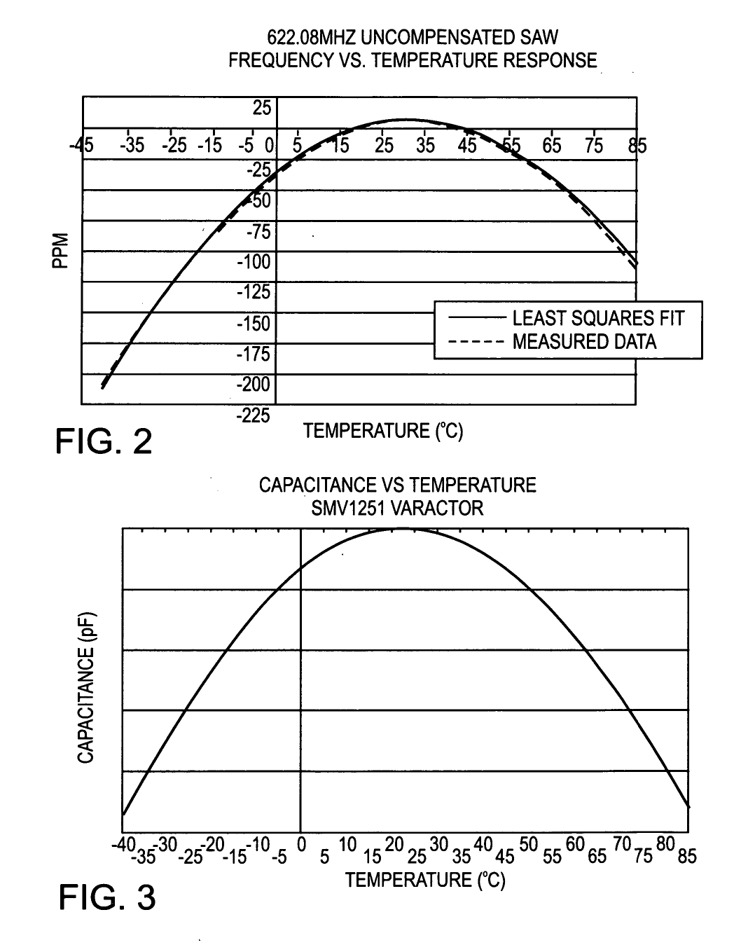

Referring to FIG. 2, the frequency change versus temperature response of an uncompensated SAW oscillator can be modeled with the mathematical form of a parabola:
f(T)=AT²+BT+C (Equation 1)
where T is temperature, f is frequency, and A, B, and C are constants which adjust the shape of the parabolic response. FIG. 2 shows the frequency versus temperature response of a SAW-based 622.08 MHz voltage controlled SAW oscillator by CTS Corporation having a part number VCS1001A along with its best fit to a parabola.

In order to compensate for the inherent frequency versus temperature SAW resonator response, reactance generator 40, coupled via signal conditioner 30 to temperature sensor 20, is used to produce a capacitance versus temperature response of the form:
C(T)XT²+YT+Z (Equation 2)
where C is capacitance, T is temperature, and constants X, Y, and Z adjust the shape of the parabolic response. FIG. 3 shows this capacitance versus frequency response utilizing SMV1251 varactors.

The compensation technique of this invention can be described by Equation 3 below where decreasing capacitance (C load ↓) corresponds to an increase in frequency (freq ↑) and increasing capacitance (C load ↑) corresponds to a decrease in frequency (freq ↓):

$$Frequency = \frac{1}{2 π \sqrt{LC}} \qquad ( Equation 3 )$$

In Equation 3 above, capacitance C is the reactance generator and hence a component of the load that the SAW resonator 60 is subjected to.

Referring to FIG. 2 and utilizing Equation 3, it can be seen that at the respective extreme cold and hot temperatures, the capacitive loading (CL) seen by the SAW resonator would need to be lower than the capacitance seen at the nominal frequency referenced to 32 degrees Centigrade. Therefore, the capacitance versus temperature response of a properly temperature compensated SAW oscillator would require the form shown in Equation 2. The present invention provides a circuit and method to create the reactance response described by Equation 3.

The graph of FIG. 2 was produced from actual circuit measurements using an HP model 53132 frequency counter.

Temperature compensation circuit 30 of the present invention can provide frequency versus temperature performance that can be +/−5 ppm or better over a temperature range of −40 to +85 degrees Centigrade.

Temperature sensor 20 creates a voltage versus temperature response that is similar to the mathematical form of a line:
V(T)=+/−M*(T)+B (Equation 4)
where V is voltage, T is temperature, M is the slope of the line, and B is the voltage offset. Temperature sensor 20 should be located as close as possible to SAW resonator 60 in order to capture the true thermal gradient of SAW resonator 60.

A forward biased transistor Q1 is used in temperature sensor 20. Other temperature sensors can be used such as thermistors or IC temperature sensors provided the response described in Equation 4 is adequate.

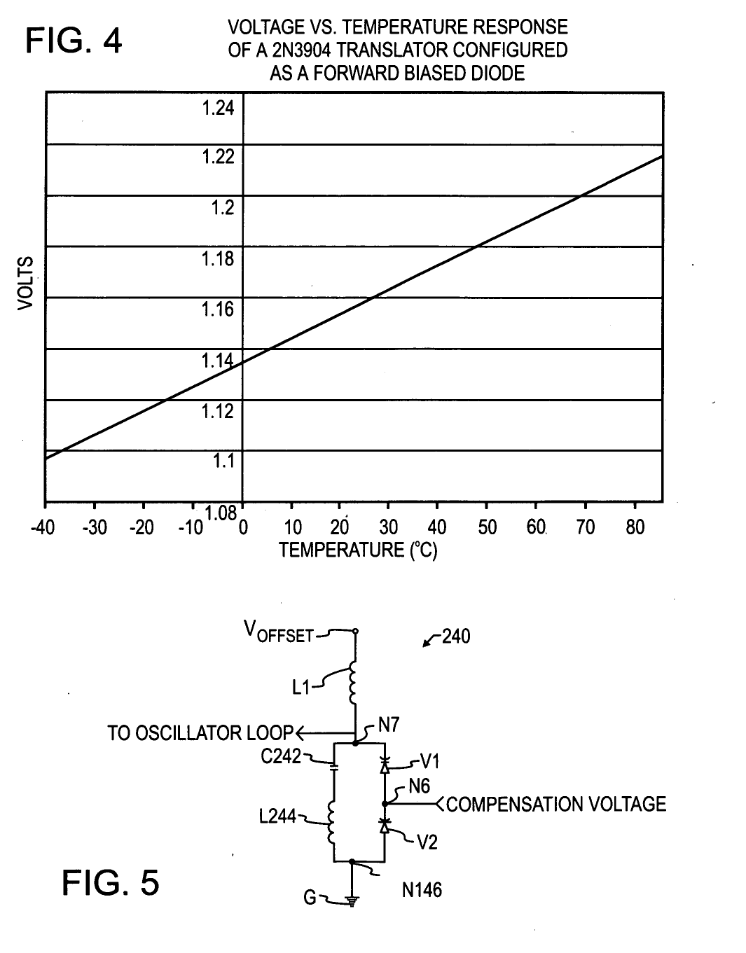

FIG. 4 illustrates the voltage versus temperature response of a single forward biased diode. The diode can be a model number MMBT3904 BJT made by ON Semiconductor of Phoenix, Ariz.

With reference to FIG. 1, signal conditioning circuit 30 receives the temperature sensor signal from temperature sensor 20 at node N1 and adjusts the slope and/or the offset of the temperature sensor signal before sending or applying a conditioned temperature sensor signal to the reactance generator 40 at node N6.

Differential amplifier U1 can be a model number LM324 amplifier made by Texas Instruments of Dallas, Tex. Variable resistors R4 and R5 preferably are digitally adjusted potentiometers that are commercially available from Xicor Corporation and adapted to control the gain, slope, and offset of the temperature sensor signal received from temperature sensor 20. Resistors R4 and R5 controlling the gain, slope, and offset are adjusted by another computer (not shown), while monitoring the output frequency. In this manner, the optimum compensated temperature signal is derived. Once the optimum values for resistors R4 and R5 are found, the computer either permanently sets resistors R4 and R5 to those values or records the optimum discrete resistor value to be placed in component positions R4 and R5.

Reactance generator circuit 40 comprises two identical type varactors V1 and V2 having V1A's anode connected to V2C's cathode with the conditioned temperature sensor signal being applied to node N6.

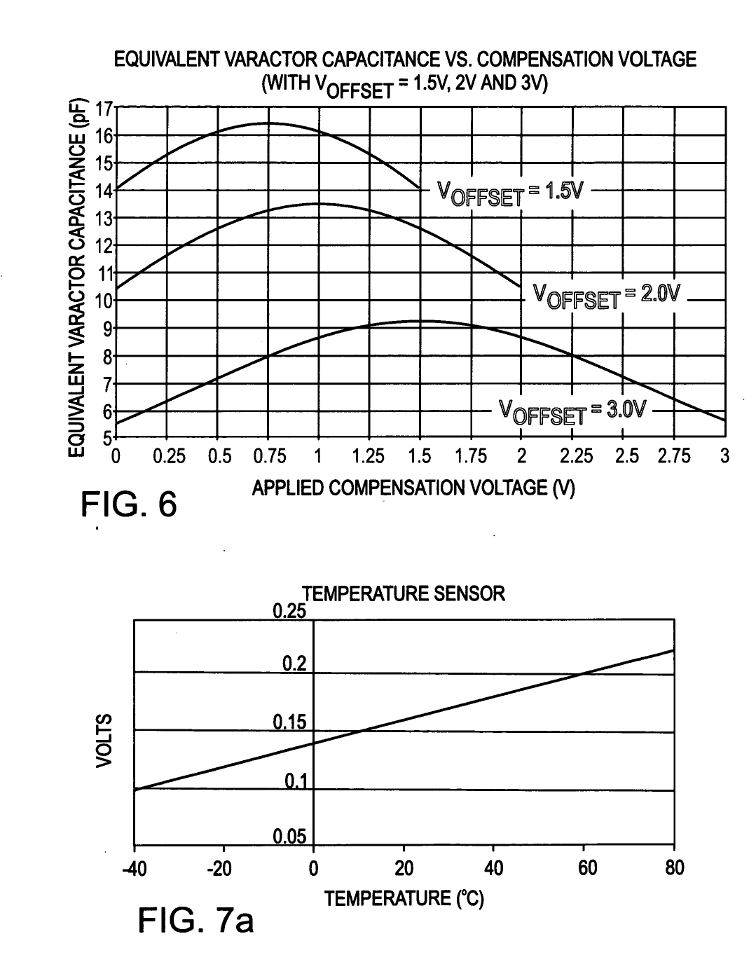

FIG. 6 depicts a sweep of the conditioned temperature sensor signal voltage from 0 to “Voffset” volts across varactors V1 and V2 with respective Voffset potentials of 1.5V, 2.0V, and 3.0V. In other words, FIG. 6 shows the output of reactance generator circuit 40.

It is noted that resistor R5 of the signal conditioning circuit 30, in conjunction with the reactance generator 40, has the primary function of adjusting the Voffset voltage seen by the reactance generator. The Voffset voltage selects capacitance offset seen in the oscillator loop 50. Resistor R4 of the signal conditioning circuit 30 has the primary function of selecting the range of the parabolic capacitance change required, over the temperature range of interest.

For a more compact package and to reduce cost, the temperature sensor 20, the signal conditioning circuit 30, the varactors 40 and oscillator 50 could be integrated into a single integrated circuit (IC).

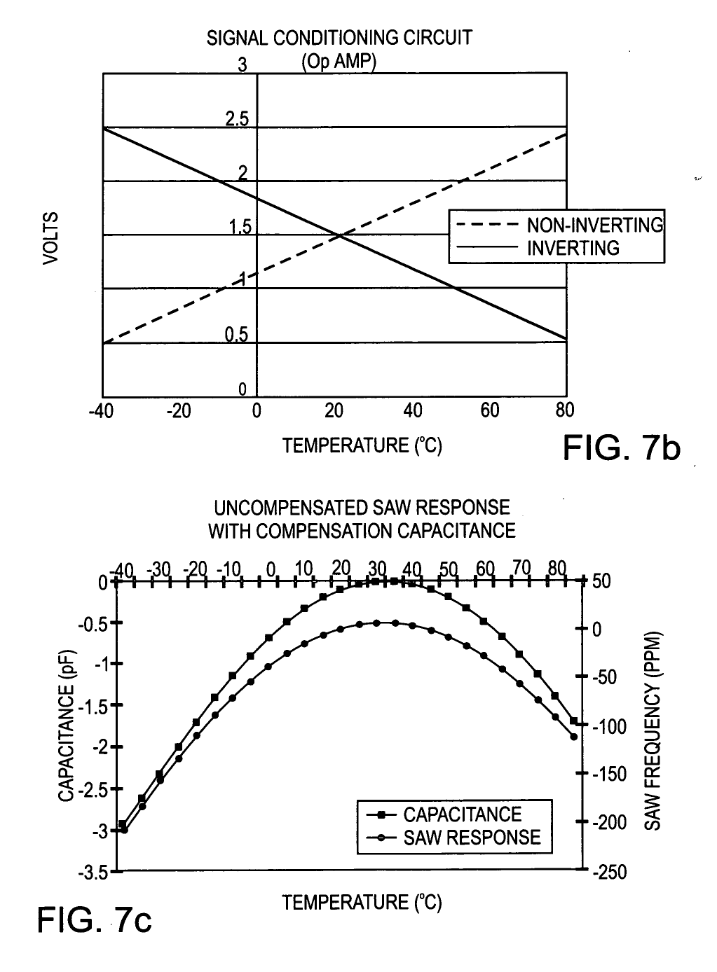

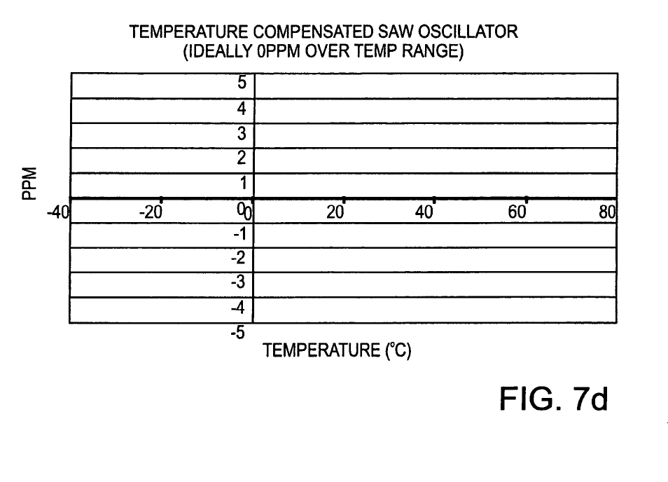

FIGS. 7a-7d illustrate the temperature compensation of oscillator 10. FIG. 7a shows a graph of the voltage versus temperature response that is generated by temperature sensor 20, i.e., the temperature sensor signal which is provided to temperature signal conditioner 30. The temperature sensor signal is applied to the input of the signal conditioning circuit 30 at node N2, where R4 and R5 are adjusted to “condition” the input signals. Based on the best solution for R4 and R5, a conditioned temperature sensor signal is generated. This signal is shown in FIG. 7b which shows a graph of voltage versus frequency at node N6, i.e., the output of signal conditioning circuit 30. The conditioned temperature sensor signal is provided or applied to the reactance generator 40 at node N6.

Reactance generator 40 generates a compensation signal which is shown in FIG. 7c. FIG. 7c shows how the varactor capacitance versus temperature response of the present invention as applied at node N7 with the use of Equation 3, can be used to temperature compensate SAW resonator 60. The compensation signal is provided to SAW resonator 60 at node N7.

Osillator circuit 50 generates an output frequency that is stabilized around a nominal frequency at which SAW resonator 60 resonates. FIG. 7d illustrates the resulting oscillator output frequency versus temperature response of oscillator 10 showing no frequency drift with temperature.

FIG. 5 depicts an alternative reactance generator configuration. Reactance generator 240 is similar to reactance generator 40 except that a series combination of an inductor L244 and capacitor C242 have been connected in parallel across the series connected combination of varactors V1 and V2. Capacitor C242 can have a value of 0.01 microfarads. Capacitor C242 is connected to cathode V1C at node N7. Inductor L244 is connected to anode V2A at node N146.

The addition of inductor L224 in parallel with the varactors provides for the adjustment of the apparent overall inductance of inductor L224 rather than simply the varactor capacitance of reactance generator 240.

The present invention provides an improvement over previous temperature compensated ocillators. The present invention allows the frequency versus temperature sensitivity of a SAW oscillator to be reduced significantly and provides a method to set the oscillator onto its desired frequency.

The use of signal conditioning circuit 30 and reactance generator 40 provides the ability to temperature compensate any SAW oscillator. The ability to select the voltage versus temperature function applied to the varactors provides the ability to compensate each individual SAW to its respective tolerance and oscillator tolerance.

The oscillator shown in the present specification is of a Colpitts configuration. However, this is not a requirement of the invention, and the oscillator may be of other oscillator configurations including, but not limited to Clapp, Driscoll, Butler, Pierce, and Hartley oscillator configurations.

The oscillator shown in the present specification utilizes a SAW resonator. However, it is contemplated that any other type of resonator could be used including, but not limited to, quartz crystals, FBAR, lithium niobate, lead zirconium titanates and other piezoelectric materials.

Oscillator assembly 10 would be packaged and assembled using conventional electronic manufacturing techniques.

While the invention has been taught with specific reference to these embodiments, someone skilled in the art will recognize that changes can be made in form and detail without departing from the spirit and the scope of the invention. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. An oscillator comprising:
a) a temperature sensor adapted to generate a temperature sensor signal;
b) a temperature signal conditioner coupled to the temperature sensor, the temperature signal conditioner receiving the temperature sensor signal and generating a conditioned temperature sensor signal;
c) a reactance generator coupled to the temperature signal conditioner, the reactance generator receiving the conditioned temperature sensor signal and generating a compensation signal;
d) a resonator device coupled to the reactance generator; and
e) an oscillator circuit coupled to the resonator device, the oscillator producing a stable output frequency over a temperature range.

2. The oscillator according to claim 1, wherein the reactance generator comprises:
a first varactor having a first cathode and a first anode;
a second varactor having a second cathode and a second anode, the anode of the first varactor being connected to the cathode of the second varactor.

3. The oscillator according to claim 1, wherein the temperature signal conditioner comprises:
an amplifier having a first and second input terminal and an output terminal, the output terminal connected to the reactance generator, the first input terminal connected to the temperature sensor;
a first filter connected to the output terminal;
a first adjustable resistor connected between the first input terminal and the output terminal; and
a second adjustable resistor connected to the second input terminal.

4. The oscillator according to claim 1, wherein the oscillator comprises:
a transistor having a base, a collector, and an emitter, and the base is connected to the resonator device.

5. The oscillator according to claim 2, wherein the first cathode is connected to the surface acoustic wave device and the second anode is connected to ground.

6. The oscillator according to claim 2, wherein an inductor and a capacitor are connected in series between the anode of the second varactor and the cathode of the first varactor.

7. The oscillator according to claim 1, wherein the resonator device is a surface acoustic wave device.

8. An oscillator comprising:
a temperature sensor for generating a temperature sensor signal;
a temperature signal conditioner coupled to the temperature sensor, the temperature signal conditioner receiving the temperature sensor signal and generating a conditioned temperature sensor signal;
a reactance generator having first and second varactors, the varactors being connected together at a first node, the temperature signal conditioner being connected to the first node, the reactance generator receiving the conditioned temperature sensor signal and generating a compensation signal;
an oscillator circuit having an output port; and
a surface acoustic wave device connected between the reactance generator and the oscillator circuit, the oscillator producing a stable output frequency over a predetermined temperature range.

9. The oscillator according to claim 8, wherein the first varactor has a first cathode and a first anode and the second varactor has a second cathode and a second anode, the anode of the first varactor being connected to the cathode of the second varactor.

10. The oscillator according to claim 8, wherein the first cathode is connected to the surface acoustic wave device and the second anode is connected to ground.

11. An oscillator comprising:
temperature sensor means for generating a temperature sensor signal;
signal conditioner means coupled to the temperature sensor for receiving the temperature sensor signal and generating a conditioned temperature sensor signal;
reactance generator means coupled to the signal conditioner means for receiving the conditioned temperature sensor signal and generating a compensation signal;
resonator means coupled to the reactance generator means for stabilizing an oscillator signal; and
oscillator means coupled to the resonator means for generating the oscillator signal.

12. The oscillator according to claim 11, wherein the reactance generator means comprises:
a first varactor having a first cathode and a first anode;
a second varactor having a second cathode and a second anode; and
the anode of the first varactor is connected to the cathode of the second varactor.

13. The oscillator according to claim 11, wherein the signal conditioner means comprises:
an amplifier having first and second input terminals and an output terminal, the output terminal being connected to the reactance generator means, the first input terminal being connected to the temperature sensor means;
a first filter connected to the output terminal;
a first adjustable resistor connected between the first input terminal and the output terminal; and
a second adjustable resistor connected to the second input terminal.

14. The oscillator according to claim 11, wherein the oscillator means comprises:
a transistor having a base, a collector, and an emitter, and the base is connected to the resonator means.

15. The oscillator according to claim 11, wherein the first cathode is connected to the resonator means and the second anode is connected to ground.

16. The oscillator according to claim 11, wherein the resonator device is a surface acoustic wave device.

17. A method of operating an oscillator, but not necessarily in the order shown, comprising the steps of:
sensing a temperature;
generating a temperature sensor signal;
providing the temperature sensor signal to a temperature signal conditioner;
generating a conditioned temperature sensor signal;
providing the conditioned temperature sensor signal to a reactance generator;
generating a compensation signal;
generating an oscillator signal; and
providing the compensation signal to a resonator device.

18. The method according to claim 17 further comprising the step of stabilizing the oscillator signal with the resonator device.

19. The method according to claim 17 further comprising the step of setting at least one resistor value in the temperature signal conditioner.
